(19) United States
(12) Patent Application Publication
(10) Pub. No.: US 2009/0220792 A1
(43) Pub. Date: Sep. 3, 2009

(54) Synthesis of Alloyed Nanocrystals in Aqueous or Water-Soluble Solvents

(75) Inventors: Jackie Y. Ying, The Nanos (SG); Yuangang Zheng, The Nanos (SG)

Correspondence Address: WOLF GREENFIELD & SACKS, P.C., 600 ATLANTIC AVENUE, BOSTON, MA, 02210-2206, US

(73) Assignee: Singapore Agency for Science, Tech and Research, Singapore (SG)

(21) Appl. No.: 12/087,841

(22) PCT Filed: Jan. 20, 2006
(86) PCT No.: PCT/US2006/002065

§ 371 Date: Jan. 14, 2009

(51) Int. Cl. C30B 29/60

(52) U.S. Cl. 428/403

(57) ABSTRACT

The present invention relates to nanocrystals and methods for making the same; in particular, the invention relates to ternary or higher alloyed nanocrystals and methods for making such structures in aqueous or water-soluble solvents. In certain embodiments of the invention, methods of preparing ternary or higher alloyed nanocrystals involve providing at least first, second, and third nanocrystal precursors (e.g., NaHSe, ZnCl₂, and CdCl₂) and forming nanocrystal structures in an aqueous or water-soluble solvent. In some cases, nanocrystal precursor solutions may also include a water-soluble ligand (e.g., glutathione, GSH). As such, ternary or higher alloyed nanocrystals (e.g., ZnₓCd)—ₓSe) comprising the at least first, second, and third nanocrystal precursors may be formed, and the water-soluble ligand may coat at least a portion of the surface of the ternary or higher alloyed nanocrystal. Advantageously, methods for forming nanocrystals described herein can be performed at low temperatures (e.g., less than 100 degrees Celsius), and, in some embodiments, do not require the use of organic solvents. The present inventors have applied these methods to prepare blue-emitting nanocrystals with emissions that are tunable between 400-500 nm, and with quantum yields of greater than 25% in aqueous solution. These nanocrystals may be highly water soluble and can be used in a variety of applications, including those involving cell culture, sensing applications, fluorescence resonance energy transfer, and in light-emitting devices.

### FIELD OF INVENTION

The present invention relates to nanocrystals and methods for making the same; in particular, the invention relates to alloyed nanocrystals and methods for making such structures in aqueous or water-soluble solvents.

### BACKGROUND

Nanocrystals are crystalline particles of matter having dimensions on the nanometer scale. Of particular interest are a class of nanocrystals known as semiconductor nanocrystals, or quantum dots, that exhibit properties that make them particularly useful in a variety of applications, including photoelectronics, lasers, and biological imaging. Because of quantum confinement effects, semiconductor nanocrystals can exhibit optical properties depending on the size, shape, and/or composition of the nanocrystals. The nanocrystals give rise to a class of materials whose properties include those of both molecular and bulk forms of matter. When these nanocrystals are irradiated at an absorbing wavelength, energy is released in the form of photons and light emission in a color that is characteristic of the size of the nanocrystals. The resulting photons that are released typically exhibit a shorter wavelength than those released from a bulk form of the same material. Therefore, smaller nanocrystals typically exhibit shorter emitted photon wavelength. For example, nanocrystals of cadmium selenide (CdSe) can emit across the entire visible spectrum when the size of the crystal is varied over the range of from two to six nanometers.

Another aspect of semiconductor nanocrystals is that crystals of a uniform size typically are capable of a narrow and symmetric emission spectrum regardless of excitation wavelength. Thus, if nanocrystals of different sizes are employed, different emission colors may be simultaneously obtained from a common excitation source. These capabilities contribute to the nanocrystals' potential as diagnostic tools, for example, as fluorescent probes in biological labeling and diagnostics.

A different strategy of tuning the fluorescence color of nanocrystals without changing the crystallite size has been achieved with core/shell composites and alloyed nanocrystals. However, many of these nanocrystals show insufficient long-term stability and insufficient luminescence in aqueous or water-soluble solutions. Consequently, it remains a major goal to develop new synthetic methods or strategies for producing luminescent stable nanocrystals in general, especially those that are blue-emitting. New synthesis methods for nanocrystals with controllable compositions and properties are important for a variety of applications.

### SUMMARY OF THE INVENTION

Alloyed nanocrystals and methods for making such structures in aqueous or water-soluble solvents are provided.

In one aspect, the invention provides a series of methods. In one embodiment, a method of preparing a ternary or higher alloyed nanocrystal comprises providing at least first and second nanocrystal precursors, forming a nanocrystal structure comprising the at least first and second nanocrystal precursors in an aqueous or water-soluble solvent, providing at least a third nanocrystal precursor and a water-soluble ligand, and forming a ternary or higher alloyed nanocrystal comprising the at least first, second, and third nanocrystal precursors in an aqueous or water-soluble solvent, wherein the ligand coats at least a portion of the surface of the ternary or higher alloyed nanocrystal.

In another embodiment, a method of preparing a ternary or higher alloyed nanocrystal comprises providing an aqueous or water-soluble nanocrystal precursor solution comprising a nanocrystal structure comprising at least first and second nanocrystal precursors, mixing the nanocrystal precursor solution and a nanocrystal precursor solution comprising at least a third nanocrystal precursor, and forming a ternary or higher alloyed nanocrystal comprising the at least first, second, and third nanocrystal precursors.

In another embodiment, a method of preparing a ternary or higher alloyed nanocrystal comprises providing an aqueous or water-soluble nanocrystal precursor solution comprising at least a first nanocrystal precursor, providing an aqueous or water-soluble nanocrystal precursor solution comprising at least a second nanocrystal precursor and a water-soluble ligand, mixing the first and second nanocrystal precursor solutions, forming a nanocrystal structure comprising the at least first and second nanocrystal precursors, mixing an aqueous or water-soluble nanocrystal precursor solution comprising the nanocrystal structure and an aqueous or water-soluble nanocrystal precursor solution comprising at least a third nanocrystal precursor and the water-soluble ligand, and forming a ternary or higher alloyed nanocrystal comprising the at least first, second, and third nanocrystal precursors, wherein the water-soluble ligand coats at least a portion of the surface of the ternary or higher alloyed nanocrystal.

In another embodiment, a method of preparing a ternary or higher alloyed nanocrystal comprises providing at least first and second nanocrystal precursors, forming a nanocrystal structure comprising the at least first and second nanocrystal precursors at a temperature of less than or equal to 100 degrees Celsius, providing at least a third nanocrystal precursor, and forming a ternary or higher alloyed nanocrystal comprising the at least first, second, and third nanocrystal precursors at a temperature of less than or equal to 100 degrees Celsius, wherein the quantum yield of the ternary or higher alloyed nanocrystal is greater than or equal to 10% in aqueous solution.

In another embodiment, a method of preparing a nanocrystal comprises providing at least first and second nanocrystal precursors, forming a nanocrystal comprising the at least first and second nanocrystal precursors in an aqueous or water-soluble solvent, wherein the nanocrystal emits electromagnetic radiation in the range between 400 and 500 nanometers, and wherein the nanocrystal has a quantum yield of at least 10% in aqueous solution.

In another aspect, the invention provides a series of structures. In one embodiment, a ternary or higher alloyed nanocrystal structure comprises a ternary or higher alloyed nanocrystal comprising at least first, second, and third nanocrystal precursors, and a coating of a water-soluble ligand on at least a portion of the ternary or higher alloyed nanocrystal surface, wherein the nanocrystal and coating form a ternary or higher alloyed nanocrystal structure having at least one cross-sectional dimension of less than 6 nanometers, and wherein the ternary or higher alloyed nanocrystal structure emits electromagnetic radiation in the range between 400 and 500 nanometers and has a quantum yield of at least 10% in aqueous solution.

In another embodiment, a ternary or higher alloyed nanocrystal structure comprises a ternary or higher alloyed nanocrystal comprising the reaction product of at least first, second, and third nanocrystal precursors, and a coating of less than or equal to 0.5 nm thickness of an amine-terminating, water-soluble ligand on at least a portion of the ternary or higher alloyed nanocrystal surface, wherein the nanocrystal and coating form a ternary or higher alloyed nanocrystal structure that emits electromagnetic radiation in the range between 400 and 500 nanometers and has a quantum yield of at least 10% in aqueous solution.

In another embodiment, a ternary or higher alloyed nanocrystal structure comprises a ternary or higher alloyed nanocrystal comprising at least first, second, and third nanocrystal precursors, and a coating comprising glutathione on at least a portion of the ternary or higher alloyed nanocrystal surface.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control. If two or more documents incorporated by reference include conflicting and/or inconsistent disclosure with respect to each other, then the document having the later effective date shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIG. 1 shows absorption and fluorescent spectra of glutathione-coated nanocrystals, according to one embodiment of the invention;

FIG. 2 shows absorption and fluorescent spectra of ZnSe precursor nanocrystals before Cd injection, and Zn_{0.4}Cd_{0.6}Se alloyed nanocrystals after Cd injection and heating, according to another embodiment of the invention;

FIG. 3 shows fluorescents peak emission wavelengths and quantum yields for ZnₓCd₁₋ₓSe nanocrystals of different compositions, according to another embodiment of the invention;

FIG. 4 shows powder X-ray diffraction patterns of glutathione-coated nanocrystals, according to another embodiment of the invention;

FIG. 5 shows high resolution TEM images of ZnSe and Zn_{0.4}Cd_{0.6}Se nanocrystals, according to another embodiment of the invention; and

FIG. 6 shows quantum yields and emission wavelengths of a series of nanocrystals, according to another embodiment of the invention.

### DETAILED DESCRIPTION

The present invention relates to nanocrystals and methods for making the same; in particular, the invention relates to ternary or higher alloyed nanocrystals and methods for making such structures in aqueous or water-soluble solvents. In certain embodiments of the invention, methods of preparing ternary or higher alloyed nanocrystals involve providing at least first, second, and third nanocrystal precursors (species that can react to form nanocrystals, e.g., NaHSe, ZnCl₂, and CdCl₂), and forming nanocrystal structures in an aqueous or water-soluble solvent. In some cases, nanocrystal precursor solutions may also include a water-soluble ligand (e.g., glutathione, GSH). As such, ternary or higher alloyed nanocrystals (e.g., ZnₓCd₁₋ₓSe) comprising the at least first, second, and third nanocrystal precursors may be formed, and the water-soluble ligand may coat at least a portion of the surface of the ternary or higher alloyed nanocrystal. Advantageously, methods for forming nanocrystals described herein can be performed at low temperatures (e.g., less than 100 degrees Celsius), and, in some embodiments, do not require the use of organic solvents. Another aspect of the invention involves nanocrystals comprising the reaction product of precursors described herein. The present inventors have applied these methods to prepare blue-emitting nanocrystals with emissions that are tunable between 400-500 nm, and with quantum yields of greater than 25% in aqueous solution. These nanocrystals may be highly water soluble and can be used in a variety of applications, including those involving cell culture, sensing applications, fluorescence resonance energy transfer, and in light-emitting devices.

“Ternary” nanocrystals, as used herein, means nanocrystals made of tlree (typically inorganic) elements. “Ternary or higher” means such nanocrystals that can include tlree or more such elements, e.g., quaternary nanocrystals include four such elements. “Quantum yield” is a physical parameter the meaning of which is well understood in the art.

The present inventors have developed new aqueous or water-soluble synthesis methods for the production of ternary or higher alloyed nanocrystals. These methods enable the use of water-soluble ligands that can form coatings on the nanocrystals; thus, new nanocrystal structures having unique properties can be formed, which may not be readily synthesized in organic solvents. For instance, in some cases these methods allow the formation of ternary or higher alloyed nanocrystals having thin coatings (e.g., less than 1 nm thick) of a water-soluble ligand. In some embodiments, ternary or higher alloyed nanocrystals synthesized in aqueous or water-soluble solvents are smaller in size (e.g., having a cross sectional dimension of less than 4 nm) compared to nanocrystals synthesized in organic solvents (which may have cross sectional dimensions of about 6 nm).

Although nanocrystals (i.e., quantum dots) of the composition ZnₓCd₁₋ₓSe are described predominately, the methods described herein can be extended to large-scale production of ternary or higher alloyed nanocrystals of various material compositions, such as HgₓCd₁₋ₓTe and PbₓCd₁₋ₓTe nanocrystals.

In certain embodiments of the invention, methods of preparing ternary or higher alloyed nanocrystals in aqueous or water-soluble solution are provided. In some cases, forming ternary or higher alloyed nanocrystals involves first forming a nanocrystal precursor structure comprising at least first and second nanocrystal precursors in an aqueous or water-soluble solvent. For instance, the first and second nanocrystal precursors may react to form at least a binary nanocrystal precursor. In some embodiments, the binary nanocrystal precursor may be a semiconductor nanocrystal, i.e., the first and/or second nanocrystal precursors may include semiconductor materials. “Water-soluble”, as used herein in the context of solvents or solutions, is given its ordinary meaning in the art, namely, that more than a trace amount is soluble in (miscible with) water. E.g., at least 1% by volume, or at least 5% by volume (of the total mixed fluid) of the “water-soluble” solvent or solution is miscible with water.

Nanocrystals (including nanocrystal precursors) of the invention may have any suitable material composition. For example, a nanocrystal of the invention may be comprised of one or more elements selected from Groups 2, 7, 8, 9, 10, 11, 12, 13, 14, 15, and 16 of the Periodic Table of Elements. These Groups are defined according to IUPAC-accepted nomenclature as is known to those of ordinary skill in the art. In some cases, a nanocrystal may be at least partially comprised of Group 12-16 compounds such as semiconductors. The semiconductor materials may be, for example, a Group 12-16 compound, a Group 13-14 compound, or a Group 14 element. Suitable elements from Group 12 of the Periodic Table of Elements may include zinc, cadmium, or mercury. Suitable elements from Group 13 may include, for example, gallium or indium. Elements from Group 14 that may be used in semiconductor nanocrystals may include, e.g., silicon, germanium, or lead. Suitable elements from Group 15 that may be used in semiconductor materials may include, for example, nitrogen, phosphorous, arsenic, or antimony. Appropriate elements from Group 16 may include, e.g., sulfur, selenium, or tellurium.

A nanocrystal precursor of the invention may include any suitable, species that can react to form a nanocrystal (or nanocrystal structure, used interchangeably herein), e.g., NaHSe, ZnCl₂, and CdCl₂ may be used as nanocrystal precursors to ZnₓCd₁₋ₓSe nanocrystals. A wide variety of nanocrystal precursors can be used to form a nanocrystal (or nanocrystal precursor structure) of the invention. For instance, when the first, second, third, or fourth, or higher nanocrystal precursor includes a Group 12 element (e.g., Zn, Cd, or Hg), the Group 12 precursor may include, i.e., a Group 12 metal oxide, a Group 12 metal halide, or a Group 12 metal organic complex. Non-limiting examples of such Group 12 structures include zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, cadmium acetate, cadmium acetylacetonate, cadmium iodide, cadmium bromide, cadmium chloride, cadmium fluoride, cadmium carbonate, cadmium nitrate, cadmium oxide, cadmium perchlorate, cadmium phosphide, cadmium sulfate, mercury acetate, mercury iodide, mercury bromide, mercury chloride, mercury fluoride, mercury cyanide, mercury nitrate, mercury oxide, mercury perchlorate, mercury sulfate, and mixtures thereof.

In another example, when one or more of the first, second, third, or higher nanocrystal precursors includes a Group 16 element (e.g., sulfur, selenium, tellurium, or an alloy thereof), the Group 16 precursor may include S powders, Se powders, Te powders, trimethylsilyl sulfur, trimethylsilyl selenium, or trimethylsilyl tellurium.

Examples of binary semiconductor nanocrystals, which can act as precursors (e.g., nanocrystal precursor structures) for ternary or higher alloyed nanocrystals, include, but are not limited to, MgO, MgS, MgSe, MgTe, CaS, CaSe, CaTe, SrS, SrSe, SrTe, BaS, BaSe, BaTe, ZnO, ZnS, ZnSe, ZnTe, CdO, CdS, CdSe, CdTe, HgO, HgS, HgSe, HgTe, AlN, AlP, AlAs, AlSb, Al₂S₃, Al₂Se₃, Al₂Te₃, Ga₂S₃, Ga₂Se₃, GaTe, In₂S₃, In₂Se₃, InTe, SnS, SnSe, SnTe, PbS, PbSe, PbTe, AlP, AlAs, AlSb, GaN, GaP, GaAs, GaSb, InN, InP, InAs, InSb, TiN, TiP, TiAs and TiSb. The specific composition may be selected, in part, to provide the desired optical properties.

In some embodiments, a first nanocrystal precursor may be added to a second nanocrystal precursor in the presence of a ligand, e.g., a water-soluble ligand, such as glutathione. A “water-soluble ligand”, as used herein is a ligand that is at least partially soluble (miscible with) water. I.e., more than a trace amount (e.g., at least about 1%) of the “water soluble ligand” may be soluble in (miscible with) water. A variety of water-soluble ligands can be used, as discussed in more detail below. The first and second nanocrystal precursors may form a binary nanocrystal precursor structure, and the water-soluble ligand may at least partially coat the surface of the nanocrystal (i.e., form an outer layer of the ligand on the nanocrystal surface). For instance, the water-soluble ligand may coat greater than 15%, greater than 30%, greater than 50%, greater than 75%, greater than 90%, or about 100% of the surface of the nanocrystal precursor structure. In some cases, the water-soluble ligand may form a monolayer (e.g., a self-assembled monolayer (SAM)) on all or portions of the nanocrystal surface. Additionally or alternatively, ligands of more than one chemical structure can be added to a nanocrystal precursor solution. The ligands may form, for instance, a mixed SAM on all or portions of the nanocrystal surface. Advantageously, forming a nanocrystal precursor structure from first and second nanocrystal precursors in the presence of a ligand can aid in the formation of ternary or higher alloyed nanocrystals in some cases. I.e., the structural properties, emission properties, and/or yield of the ternary or higher alloyed nanocrystals may be benefited by addition of a ligand during the formation of a nanocrystal precursor structure, and/or by addition of the ligand during more than one step of the synthesis (i.e., during steps of forming a nanocrystal precursor structure and forming the ternary or higher alloyed nanocrystal from the precursor structure). In some cases, presence of a ligand in a nanocrystal precursor solution stabilizes a nanocrystal precursor, i.e., at high pH (e.g., pH 9), and may prevent the formation of insoluble hydroxides.

Binary or higher alloyed nanocrystals (e.g., nanocrystal precursors) may be combined with one or more nanocrystal precursor solutions containing at least a third nanocrystal precursor to form a ternary or higher alloyed nanocrystal. The ternary or higher alloyed nanocrystal may be a reaction product of at least first, second, and third nanocrystal precursors. The ternary or higher alloyed nanocrystal may be formed in an aqueous or water-soluble solvent, and may be comprised of the at least first, second, and third nanocrystal precursors. In some cases, the ternary or higher alloyed nanocrystal is formed at low temperatures (e.g., less than or equal to 100° C., less than or equal to 95° C., or less than or equal to 85° C.).

In other embodiments, at least first, second, and third nanocrystal precursors can be combined in an aqueous or water-soluble solvent to form a ternary or higher alloyed nanocrystal, i.e., a reaction product of the at least first, second, and third nanocrystal precursors. In some cases, this can be performed without the necessity of precipitation out a binary nanocrystal precursor structure. For instance, at least first and second nanocrystal precursors may form a nanocrystal precursor structure (e.g., a binary or higher nanocrystal) in an aqueous or water-soluble solvent, and, without precipitating the precursor structure, a third nanocrystal precursor can be added to the solvent to form a ternary or higher alloyed nanocrystal (i.e., with heating/cooling of the solvent as appropriate). Sometimes, a water-soluble ligand can be present in the solvent and at least a portion of the surface of the ternary or higher alloyed nanocrystal can be coated with the ligand.

In some instances, a ternary or higher alloyed nanocrystal comprises a core formed of a binary or higher alloyed nanocrystal precursor structure, and a shell around the core formed of the at least third nanocrystal precursor. In other instances, the ternary or higher alloyed nanocrystal comprises core and shell portions that have the same structure, i.e., the ternary or higher alloyed nanocrystal may be substantially homogeneous. In other words, the distribution of nanocrystal precursors (e.g., first and second nanocrystal precursors in the case of a binary nanocrystal, or first, second, and third nanocrystal precursors in the case of a ternary nanocrystal) may be substantially homogeneous within the nanocrystals.

The ternary or higher alloyed nanocrystal may have compositions comprising alloys or mixtures of the materials listed above. Ternary alloyed nanocrystals may have a general formula of A¹ₓA²_{I-x}M, A^{I}₁₋ₓA²ₓM, A¹₁₋ₓMA²ₓ, or A¹₁₋ₓMA²ₓ; quaternary alloyed nanocrystals may have a general formula of A¹ₓA²₁₋ₓM¹_{y}M²_{1-y}, A¹₁₋ₓA²ₓM¹_{y}M²_{1-y}, A¹ₓA²₁₋ₓM¹_{1-y}M²_{y} or A¹₁₋ₓA²ₓM¹_{1-y}M²_{y}, where the index x can have a value between 0.001 and 0.999, between of 0.01 and 0.99, between 0.05 and 0.95, or between 0.1 and 0.9. In some cases, x can have a value between about 0.2, about 0.3, or about 0.4, to about 0.7, about 0.8 or about 0.9. In some particular embodiments, x can have a value between 0.01 and 0.1 or between 0.05 and 0.2. The index y may have a value between 0.001 and 0.999, between 0.01 and 0.99, between 0.05 and 0.95, between 0.1 and 0.9, or between about 0.2 and about 0.8. Identities of A and M in this context will be understood from the exemplary list of species which follows, and other disclosure herein. In some embodiments, A and M can be selected from Groups 2, 7, 8, 9, 10, 11, 12, 13, 14, 15, or 16 of the Periodic Table of Elements. For instance, in some particular embodiments, A¹ and/or A² can be selected from Groups 2, 7, 8, 9, 10, 11, 12, 13 and/or 14, e.g., while M (e.g., M¹ and/or M²) are selected from Groups 15 and/or 16 of the Periodic Table of Elements.

Non-limiting examples of ternary alloyed nanocrystals include ZnSSe, ZnSeTe, ZnSTe, CdSSe, CdSeTe, CdSTe, HgSSe, HgSeTe, HgSTe, ZnCdS, ZnCdSe, ZnCdTe, ZnHgS, ZnHgSe, ZnHgTe, CdHgS, CdHgSe, CdHgTe, ZnPbS, ZnPbSe, ZnPbTe, CdPbS, CdPbSe, CdPbTe, AlGaAs, InGaAs, InGaP, and AlGaAs. Non-limiting examples of quaternary nanocrystal alloys include ZnCdSSe, ZnHgSSe, ZnCdSeTe, ZnHgSeTe, CdHgSSe, or CdHgSeTe, ZnCdSeTe, ZnCdSeS, HgCdSeS, HgCdSeTe, GalnpAs, AlGaAsP, InGaAlP, and InGaAsP. These nanocrystals can have an appropriate bandgap by adjusting the ratio of the precursors used. The ternary or higher alloyed nanocrystals can be used as-is, or they may act as precursors for preparation of higher alloyed nanocrystal structures.

In some cases, the nanocrystal precursor solution containing the at least third nanocrystal precursor may also include a ligand, e.g., a water-soluble ligand, such as glutathione. Upon mixing the nanocrystal precursor solution with a binary or higher nanocrystal precursor structure, a ternary or higher alloyed nanocrystal may be formed, and the water-soluble ligand may coat at least a portion of the surface of the ternary or higher alloyed nanocrystal. For instance, the water-soluble ligand may coat greater than 15%, greater than 30%, greater than 50%, greater than 75%, greater than 90%, or 100% of the surface of the nanocrystal precursor structure. In some cases, the water-soluble ligand may form a monolayer (e.g., a self-assembled monolayer (SAM)) on all or portions of the nanocrystal surface. In some cases, ligands of more than one chemical structure can be added to a nanocrystal precursor solution. The ligands may form, for instance, a mixed SAM on all or portions of the nanocrystal surface.

In certain embodiments, ternary alloyed-nanocrystals having compositions such as ZnₓCd₁₋ₓSe, HgₓCd₁₋ₓTe, and PbₓCd₁₋ₓTe can be prepared in aqueous or water-soluble solvents. The nanocrystals may be coated with a water-soluble ligand such as glutathione, and the nanocrystals may have fluorescence emissions that are tunable between 400 nm and 500 nm (i.e., for ZnₓCd₁₋ₓSe nanocrystals) or between 600 nm and 800 nm (i.e., for HgₓCd₁₋ₓTe, and PbₓCd₁₋ₓTe nanocrystals), i.e., by varying the composition of the nanocrystals. The as-prepared GSH-coated nanocrystals may have quantum yields (QY) of greater than or equal to 10%, greater than or equal to 15%, greater than or equal to 20%, greater than or equal to 25%, greater than or equal to 30%, or greater than or equal to 35% in aqueous solution. In some embodiments, the nanocrystals emit electromagnetic radiation having narrow bandwidths, e.g., between 20-32 nm. Advantageously, GSH-coated ZnₓCd₁₋ₓSe, HgₓCd₁₋ₓTe, and PbₓCd₁₋ₓTe nanocrystals may be highly water-soluble and biocompatible. The as-prepared nanocrystals can be substantially monodispersed with sizes as small as 3 nm. In some cases, analytes of interest can be easily linked to ligands on these nanocrystals, i.e., by conjugation with amino or carboxyl groups. The GSH-coated ZnₓCd₁₋ₓSe nanocrystals are of great interest, i.e., as blue (ZnₓCd₁₋ₓSe) or red (HgₓCd₁₋ₓTe, and PbₓCd₁₋ₓTe) fluorescent labels for biological imaging applications (e.g., as fluorescent tags for biological and/or chemical materials).

In one embodiment defining a working example of the invention, a first aqueous precursor solution containing a first nanocrystal precursor, Zn, was mixed with a second aqueous nanocrystal precursor solution comprising a second nanocrystal precursor, Se. The mixture also contained a water-soluble ligand, glutathione. The growth of a ZnSe nanocrystal precursor structure may start soon after the heating the mixture to 95° C. The fluorescence emission peaks of the as-prepared ZnSe nanocrystals were shifted from 350 nm to 370 nm in 90 min, with quantum yields increasing from 2% to 7%. The quantum yields were measured in water at pH 9.

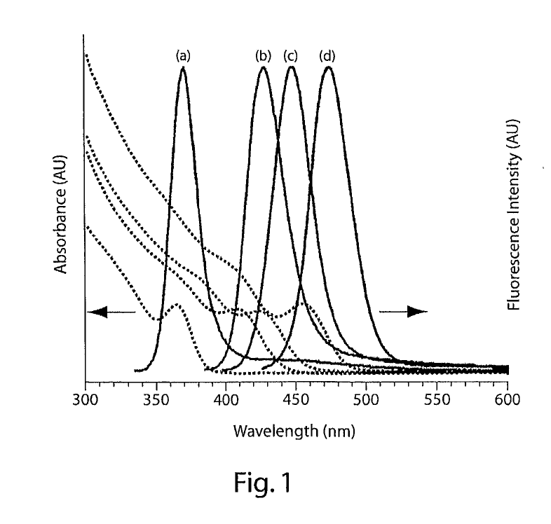

The absorption and fluorescence spectra of as-prepared ZnSe nanocrystals with 370-nm emission are shown in FIG. 1. In the embodiment illustrated in FIG. 1, the quantum yield and bandwidth of the ZnSe fluorescence emissions were 7% and 19 nm, respectively, and were dominated by band-gap emission. With further heating, the emission peak continued to shift towards longer wavelength, but the quantum yield began to decrease, most-likely due to the geometrical mismatch between the glutathione and the larger ZnSe nanocrystals. Advantageously, the GSH-coated ZnSe nanocrystals achieved 7% quantum yield without any post-preparative treatments, which can be time-consuming and may result in irreversible agglomeration of nanocrystals.

In some embodiments, binary nanocrystals (e.g., ZnSe) can be used as precursors for preparation of ternary or higher alloyed nanocrystals. A third nanocrystal precursor, e.g., Cd, can be incorporated into the binary precursor nanocrystals. In some cases, the binary nanocrystal precursor solution (e.g., a solution comprising a nanocrystal precursor such as ZnSe) can be heated at 95° C. for 0, 30, 60 or 90 min (i.e., with all other reaction conditions constant) before the introduction of the third nanocrystal precursor. The duration of heating may influence the quality, yield, and/or other properties of the reaction product, i.e., the ternary or higher alloyed nanocrystals. For instance, in one particular embodiment, alloyed nanocrystals of the best quality were obtained from addition of a third nanocrystal precursor, Cd, to the binary precursor nanocrystals, ZnSe, after the precursors were heated for 30 min. After addition of the third nanocrystal precursor, the resulting solution was heated from 4 to 6 hours at 95° C. and produced ternary alloyed nanocrystals (e.g., ZnₓCd₁₋ₓSe) having a tunable range between 400 and 500 μm, with quantum yields ranging from 10 to 27% in aqueous solution. In another particular embodiment, ternary alloyed nanocrystals of the best quality were obtained from addition of a third nanocrystal precursor (e.g., Pb(NO₃)₂ or Hg(CH₃COO)₂) to a binary nanocrystal precursor (e.g., CdTe) before heating of the binary nanocrystal precursor solution. After addition of the third nanocrystal precursor, the resulting solution was heated from 1 to 3 hours at 95° C. and produced ternary alloyed nanocrystals (e.g., PbₓCd₁₋ₓTe or HgₓCd₁₋ₓTe) having a tunable range between 600 to 800 nm, with quantum yields ranging from 10 to 30% in aqueous solution and bandwidths of less than 50 nm. Thus, the duration of heating, as well as the sequence of steps during synthesis (i.e., heating before or after addition of certain components) can influence the quality, yield, and/or other properties of the reaction product. Accordingly, one can select appropriate reaction conditions by varying one condition at a time, while keeping other conditions constant.

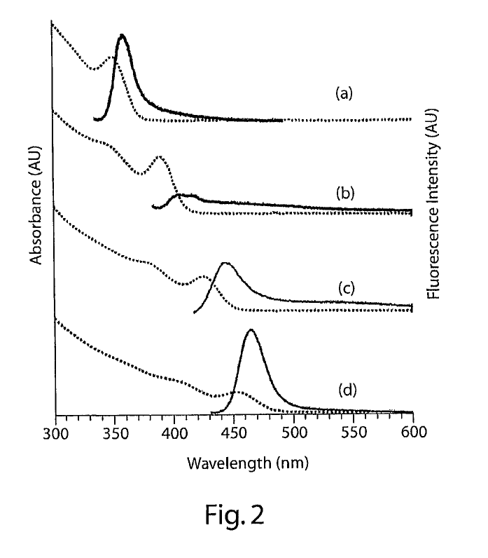

Ternary or higher alloyed nanocrystals of the invention can be tuned such that the nanocrystal emits electromagnetic radiation in the range between 400 and 500 nm, or, alternatively, between 600-800 nm, i.e., by varying the relative composition (e.g., mole fraction of components) of the nanocrystal and/or by varying the size of the nanocrystal (e.g., by varying the time allowed for heating the precursor solutions). For instance, a nanocrystal may have an emission between 415 nm and 443 nm, e.g., for some nanocrystals having an emission of 428 nm with a bandwidth of less than 30 nm. In other instances, nanocrystals may have an emission of 448 nm, or 474 nm, such that the nanocrystal emits electromagnetic radiation in the range between 400 and 500 nm. Such a description of emission as a characterizing feature herein means that at least 10% of total electromagnetic radiation emission of the nanocrystal exists within the stated wavelength range. Alternatively, in other embodiments, at least 10%, 20%, 35%, 50%, 75%, or 90% of the total emission of the nanocrystal exists within that range. For instance, the evolution of the absorption and fluorescence spectra of the GSH-coated Zn_{0.4}Cd_{0.6}Se alloyed nanocrystals is shown in the embodiment illustrated in FIG. 2. Upon addition of Cd, the Cd can be rapidly deposited on the surface of ZnSe nanocrystals, i.e., due to the high association constant of CdSe. The fluorescence of ZnSe (FIG. 2A) was mostly quenched by the addition of a layer of CdSe (FIG. 2B), and the band gap in absorption spectrum shifted from 360 nm to 405 nm. With further heating, the bandgap continued to shift towards longer wavelength, the fluorescence emission underwent a red shift, and the fluorescence intensity increased. After 1 h of heating (FIG. 2C), the band gap and fluorescence emission peak shifted by 40 nm to 445 nm, and the spectrum became dominated by band-edge emission. After 4 h of heating (FIG. 2D), the fluorescence emission peak shifted by 20 nm to 465 nm. The peak red-shifted by less than 2 nm after 2 more hours of heating, and the broad trap emission tail at the longer wavelength became almost undetectable, indicating that the composition of alloyed nanocrystals had became uniform.

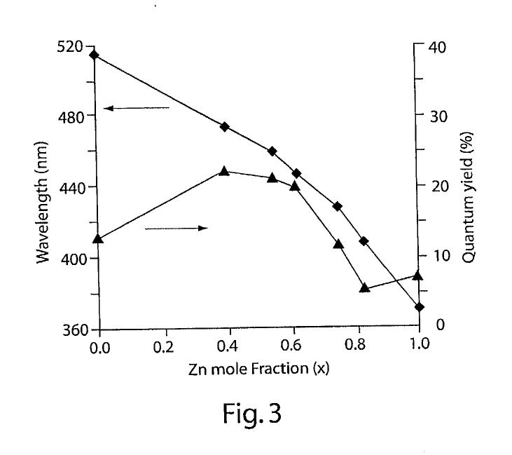

To control the relative mole fraction of Cd in the ZnₓCd₁₋ₓSe alloyed nanocrystals, precursor solutions comprising different mole ratios of Cd precursor can be mixed with the ZnSe nanocrystals, i.e. at the same time point after heating of the ZnSe precursors, and the mixtures can be heated for the same duration of time. In one embodiment, the fluorescence emission of GSH-coated ZnₓCd₁₋ₓSe alloyed nanocrystals became free of trap emission and were stable after 4 h of heating. The fluorescence spectra of Zn_{0.75}Cd_{0.25}Se, Zn_{0.62}Cd_{0.38}Se, and Zn_{0.4}Cd_{0.6}Se nanocrystals are shown in FIGS. 1(b), 1(c) and 1(d), respectively. The fluorescence peaks of the three alloyed nanocrystals were at 428, 448 and 474 nm, respectively, with narrow bandwidths of 28, 30 and 32 nm. The quantum yields measured for the Zn_{0.75}Cd_{0.25}Se, Zn_{0.62}Cd_{0.38}Se, and Zn_{0.4}Cd_{0.6}Se nanocrystals in water (pH 9) were 12%, 20% and 22%, respectively. Zn_{0.4}Cd_{0.6}Se alloyed nanocrystals having a quantum yield of 27% were also synthesized. The Zn molar fraction (x) in the ZnₓCd₁₋ₓSe alloyed nanocrystals was determined by ICP-MS elemental analysis. FIG. 3 illustrates fluorescence peak emissions and quantum yields of ZnₓCd₁₋ₓSe alloyed nanocrystals having various compositions.

Advantageously, the ZnₓCd₁₋ₓSe alloyed nanocrystals can be stable in aqueous solutions having pH 8.5-11 for longer than 7 months, and in solutions having pH 7-8 for at least 3 days, without significant changes in emission properties (i.e., quantum yield and bandwidth). The ternary or higher alloyed quantum dots are suitable, therefore, for use with cells and other biological and/or chemical materials, as discussed in more detail below.

In another embodiment, first and second nanocrystal precursors, Cd and Zn, were pre-mixed (i.e., to form a CdZn nanocrystal precursor) before addition of a third nanocrystal precursor, Se. Upon growth and purification, CdSe was the dominating component in the final nanocrystals (based on data from elemental analysis), even though the nominal mole fraction of Zn precursor was 0.8. This observation may be explained by the substantial difference between the binding affinities of Se precursor to Cd compared to Se binding with Zn (i.e., the aqueous solubility of ZnSe was much higher than CdSe; the Kₛₚ for ZnSe and CdSe were 10⁻²⁶ and 10⁻³³, respectively). The spectroscopic characteristics of the resulting nanocrystals were very similar to those of GSH-coated CdSe nanocrystals prepared with pure Cd precursors. It was concluded that in some embodiments, the approach of using Cd and Zn as first and second precursors was not as suitable as the approach of using Zn and Se as first and second precursors in forming ZnₓCd₁₋ₓSe nanocrystals with tunable alloy compositions.

Accordingly, those of ordinary skill in the art can determine appropriate materials, combinations of materials, and reaction conditions, i.e., based on physical properties of materials (e.g., binding affinities and bandgaps) and using routine experimentation, in order to obtain appropriate tunable alloy compositions. For instance, in some cases, one can generally select the order of combining first, second, and/or third nanocrystal precursors by, i.e., combining first and second nanocrystals under experimental conditions to form a nanocrystal precursor structure, and then combining a nanocrystal precursor structure with at least a third nanocrystal precursor under experimental conditions to form a first ternary or higher alloyed nanocrystal. First, second, and/or third nanocrystal precursors may be chosen, i.e., based on the relative binding affinities and bandgaps of the components. Properties of the tertiary or higher alloyed nanocrystal (e.g., yield, size, quantum yield, emission bandwidth, etc.) can then be measured. Under similar experimental conditions, a different set of nanocrystal precursors (e.g., the second and third nanocrystal precursors) can be selected and combined to form a nanocrystal precursor structure, which can then be combined with another nanocrystal precursor (e.g., the first nanocrystal precursor) to form a second ternary or higher alloyed nanocrystal. Properties of the second structure can be measured and compared to that of the first structure to determine an appropriate order of combining first, second, and/or third nanocrystal precursors. A similar approach can also be used to determine appropriate materials for first, second, third, or higher nanocrystal precursors.

Physical characterizations were performed on the GSH-coated ZnSe nanocrystals with the highest QY (7%), which showed a fluorescence emission peak at 370 nm. GSH-coated Zn_{0.75}Cd_{0.25}Se, Zn_{0.62}Cd_{0.38}Se, and Zn_{0.4}Cd_{0.6}Se alloyed nanocrystals were also examined in detail.

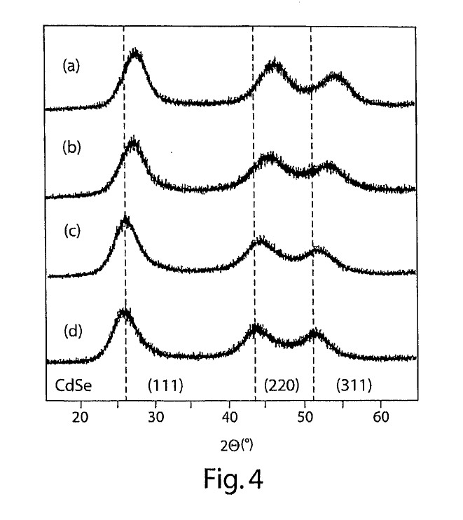

In some cases, ternary or higher alloyed nanocrystals fabricated using methods described herein have crystal structures that are different than those fabricated in organic solvents. For instance, nanocrystals formed in aqueous or water-soluble solvents may have a cubic crystal structure (e.g., zinc blend cubic crystal structure), whereas structures having similar compositions formed in organic solvents may have a hexagonal crystal structure (e.g., wurtzite crystal structures). FIG. 4 shows powder X-ray diffraction (XRD) patterns of GSH-coated ZnSe and ZnₓCd₁₋ₓSe alloyed nanocrystals having zinc blend cubic crystal structures. In some cases, the crystal structures of these nanocrystals are similar to certain other thiol-coated nanocrystals or GSH-coated CdTe nanocrystals. As the Zn molar fraction decreased from 1 to 0.4, the XRD peaks shifted toward smaller angles. The XRD peaks of GSH-coated Zn_{0.4}Cd_{0.6}Se (FIG. 4(d)) were similar to those of GSH-coated CdSe nanocrystals. Based on the bandwidths of peak (111) and Scherrer's equation, cross-sectional dimensions (e.g., core diameters) of ZnSe, Zn_{0.75}Cd_{0.25}Se, Zn_{0.62}Cd_{0.38}Se and Zn_{0.4}Cd_{0.6}Se nanocrystals were calculated to be 2.6, 2.7, 2.8 and 2.7 nm, respectively. Considering the effect of composite nanocrystals on XRD peak broadening, the actual cross-sectional dimensions of the alloyed nanocrystals should be slightly larger than the calculated size (which was based on the assumption of homogeneous crystal lattice). Thus, Zn_{0.75}Cd_{0.25}Se, Zn_{0.62}Cd_{0.38}Se and Zn_{0.4}Cd_{0.6}Se alloyed nanocrystals can have a cross sectional dimension (e.g., a core diameter) of about 3-4 nm. The synthesis of such nanocrystals in an aqueous or water-soluble solvent can produce monodispersed nanocrystals, i.e., nanocrystals that have substantially similar cross-sectional dimensions (e.g., widths of ±1 nm, lengths of ±1 nm, and/or core diameters of ±1 nm). E.g., in some cases, greater than 50%, greater than 60%, greater than 70%, greater than 80%, greater than 90%, or greater than 95% of the nanocrystals formed can be monodispersed.

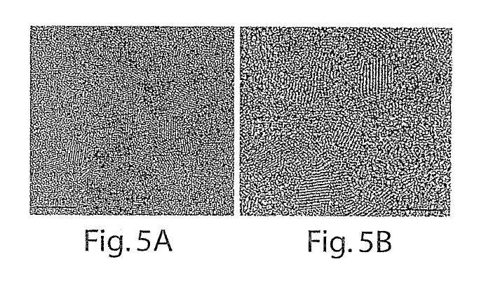

FIG. 5 shows high-resolution TEM micrographs of GSH-coated ZnSe nanocrystals (FIG. 5(a)) and Zn_{0.4}Cd_{0.6}Se alloyed nanocrystals (FIG. 5(b)). In the embodiments illustrated in FIG. 5, the nanocrystals had a first cross-sectional dimension (e.g., a length) of about 3-4 nm and a second cross-sectional dimension (e.g., a width) of about 2-3 nm. In another embodiment, greater than 90% of the nanocrystals synthesized had widths of 3.3±0.5 nm and lengths of 3.9±0.5 nm. The Zn_{0.4}Cd_{0.6}Se alloyed nanocrystals were slightly larger than the ZnSe nanocrystals. In some cases, the size distribution of the as-prepared GSH-coated alloyed nanocrystals in aqueous solution was measured by dynamic light scattering (DLS) to be 4-6 nm. I.e., since the DLS particle size reflected the nanocrystallite size and coating thickness, some nanocrystal structures comprising the ternary or higher alloyed nanocrystal and a coating of a ligand had cross-sectional dimensions of between 4-6 nm.

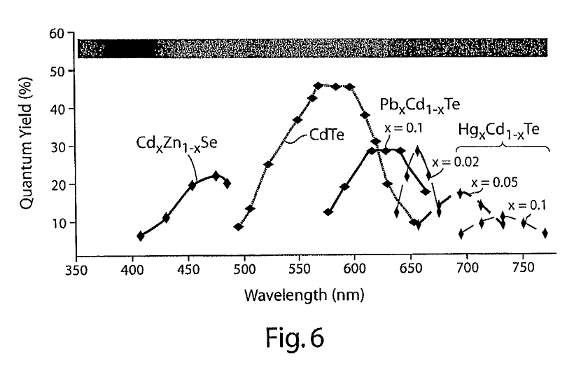

In other embodiments, ternary alloyed nanocrystals, PbₓCd₁₋ₓTe and HgₓCd₁₋ₓTe, can be produced by first forming a nanocrystal precursor structure, CdTe, i.e., in an aqueous or water-soluble solvent, from first and second nanocrystal precursors, e.g., CdCl₂ and H₂Te. A third nanocrystal precursor, e.g., Pb(NO₃)₂ or Hg(CH₃COO)₂), may be added to the nanocrystal precursor structure to form PbₓCd₁₋ₓTe or HgₓCd₁₋ₓTe, respectively. In some cases, a water-soluble ligand (e.g., glutathione) can be provided during formation of the nanocrystal precursor structure, and/or during formation of the ternary or higher alloyed nanocrystal, i.e., to produce glutathione-coated PbₓCd₁₋ₓTe and HgₓCd₁₋ₓTe nanocrystals. These structures may have tunable ranges between 600 to 800 nm and quantum yields between 10 to 30% in aqueous solution, i.e., for certain structures having values of x ranging from 0.01 to 0.1. FIG. 6 shows quantum yields and emission wavelengths of Pb_{0.1}Cd_{0.9}Te nanocrystals and HgₓCd₁₋ₓTe nanocrystals where x=0.02, 0.05, and 0.1. In some particular instances involving syntheses of PbₓCd₁₋ₓTe and HgₓCd₁₋ₓTe nanocrystals, x was the approximate amount of component in the alloyed nanocrystal.

Ternary or higher alloyed nanocrystals may be synthesized to have a variety of shapes and/or sizes. For instance, the nanocrystals may be substantially spherical, oval, or rod-like. The ternary or higher alloyed nanocrystals may have at least one cross-sectional dimension of less than 100 nm, less than 50 nm, less than 20 nm, less than 10 nm, less than 6 nm, or less than 3 μm. In some cases, the size of the ternary or higher alloyed nanocrystal may be measured in combination with a coating of a ligand (e.g., a water-soluble ligand). The combined nanostructure and coating may have a cross-sectional dimension of less than 100 nm, less than 50 nm, less than 20 nm, less than 10 nm, less than 6 nm, or less than 3 nm. In some cases, the combined nanostructure and coating may have a cross-sectional dimension between 3 and 6 nm, between 4 and 6 nm, or between 4 and 7 nm. Sizes and/or dimensions of nanocrystals may be determined using standard techniques, for example, by measuring the size of a representative number of particles using microscopy techniques (e.g., TEM and DLS).

The emission wavelength of a semiconductor nanocrystal may be governed by factors such as the size and/or composition of the nanocrystal. As such, these emissions may be controlled by varying the particle size and/or composition of the nanocrystal. For instance, for ternary alloyed nanocrystals having the structure ZnₓCd₁₋ₓSe, changing the proportion of Zn and Cd components can change the emission of the nanocrystals. For example, Zn_{0.75}Zd_{0.25}Se, Zn_{0.62}Cd_{0.38}Se and Zn_{0.4}Cd_{0.6}Se nanocrystals may be synthesized to have emissions of 428, 448, and 474 mm, respectively.

The electromagnetic radiation emitted by a ternary or higher alloyed nanocrystals of the invention may have very narrow bandwidths, for example, spanning less than about 100 nm, preferably less than about 80 nm, more preferably less than about 60 nm, more preferably less than about 50 nm, more preferably less than about 40 nm, more preferably less than about 30 nm, more preferably less than about 20 nm, and more preferably less than 15 nm. In some cases, the electromagnetic radiation emitted by a ternary or higher alloyed nanocrystal of the invention may have narrow wavelengths, such as between 10 and 20 nm, between 20 and 25 nm, between 25 and 30 nm, between 30 and 35 mm, or between 28 and 32 nm.

The nanocrystal may emit a characteristic emission spectrum which can be observed and measured, for example, spectroscopically. Thus, in certain cases, many different nanocrystals may be used simultaneously, without significant overlap of the emitted signals. The emission spectra of a nanocrystal may be symmetric or nearly so. Unlike some fluorescent molecules, the excitation wavelength of the nanocrystal may have a broad range of frequencies. Thus, a single excitation wavelength, for example, a wavelength corresponding to the “blue” region or the “purple” region of the visible spectrum, may be used to simultaneously excite a population of nanocrystals, each of which may have a different emission wavelength. Multiple signals, corresponding to, for example, multiple chemical or biological assays, may thus be simultaneously detected and recorded.

In some cases, forming a ternary or higher alloyed nanocrystal involves forming a nanocrystal precursor structure (e.g., a binary nanocrystal) and/or the ternary or higher alloyed nanocrystal in an aqueous or water-soluble solvent. For instance, one or more of the first, second, third, fourth, or higher precursors may be present in the form an aqueous or water-soluble precursor solution. Sometimes, the aqueous or water-soluble solvent may be substantially oxygen-free, e.g., water that is substantially free of O₂(g) and under an inert atmosphere (e.g., argon, nitrogen, helium, xenon, etc.). In other cases, the solvent may include an alcohol, e.g., greater than 20%, greater than 40%, greater than 60%, greater than 80%, or about 100% of the solvent (by weight) may comprise an alcohol. Non-limiting examples of alcohols suitable for use in the invention include alcohols containing from one to four carbon atoms, i.e., C₁ to C₄ alcohols, including methanol, ethanol, n-propanol, isopropanol, n-butanol, sec-butanol, and t-butanol. In some cases, alcohols having greater than four carbons can be used. Advantageously, ternary or higher alloyed nanocrystals may be prepared without the use of organic solvents and/or surfactants in some embodiments of the invention. I.e., surfactants such as trioctylphosphine oxide (TOPO) may not be required when nanocrystals coated with water-soluble ligands are synthesized in aqueous or water-soluble solvents. As a result, new nanocrystal structures having unique properties can be formed, which may not be readily synthesized in organic solvents. For instance, synthesis of ternary or higher alloyed nanostructures in aqueous or water-soluble solvents can allow the formation of thin coatings of a ligand (e.g., in some cases less than 1 nm thick) on at least a portion of the surface of the nanocrystal. Aqueous synthesis of ternary or higher alloyed nanocrystals may also lead to smaller nanocrystals (i.e., nanocrystals having a smaller cross-sectional dimension) than those synthesized in organic solvents.

Nanocrystal structures, including nanocrystal precursors and/or ternary or higher alloyed nanocrystals, may be heated in an aqueous or water-soluble solvent for various amounts of time. In some cases, alloyed nanocrystals of different quality can be obtained depending on the amount of time the nanocrystal precursors were heated in solution. In some cases, nanocrystal structures comprising at least first and second nanocrystal precursors can be heated (e.g., at temperatures of less than or equal to 100° C.) for less than or equal to about 30 minutes, less than or equal to about 60 minutes, or less than or equal to about 90 minutes, before the introduction of at least a third nanocrystal precursor. Advantageously, synthesis of nanocrystals in aqueous or water-soluble solvents requires lower reaction temperatures than synthesis of nanocrystals in organic solvents (which may require temperatures greater than 300° C.). In addition, long-term annealing (e.g., 30 hours) may not be required when synthesizing nanocrystals in aqueous or water-soluble solvents.

Following nucleation, nanocrystals may be allowed to grow until reaching the desired size and then quenched, i.e., by dropping the reaction temperature. Nanocrystal size and nanocrystal size distribution during the growth stage of the reaction may be approximated by monitoring the absorption or emission peak positions and/or line widths of the samples. Dynamic modification of reaction parameters such as temperature and precursor concentration in response to changes in the spectra may allow the tuning of these characteristics.

In certain embodiments, binary and/or ternary or higher alloyed nanocrystals can include a coating of a ligand on at least a portion of the nanocrystal surface. In some cases, the ligand may be a water-soluble ligand. The term “water soluble”, in this context, is used herein as it is commonly used in the art to refer to the dispersion of a nanocrystal in an aqueous or water-soluble environment. “Water soluble” does not mean, for instance, that each material is dispersed at a molecular level. A nanocrystal can be composed of several different materials and still be “water soluble” as an integral particle.

Water-soluble ligands may comprise functional groups such as carboxyl, amine, amide, imine, aldehyde, hydroxyl groups, the like, and combinations thereof. Such functional groups may define terminating groups of a coating (or at least partial coating) of a nanocrystal of the invention. I.e., a coating may be assembled, or may self-assemble, in association with a surface of a nanocrystal such that a particular functional group is primarily or exclusively presented outwardly relative to the nanocrystal, and an entity interacting with the nanocrystal in a standard chemical or biochemical interaction first or primarily encounters that functional group. E.g., an amine-terminating coating on a nanocrystal of the invention will primarily or exclusively present, to a species in a standard chemical or biochemical interaction with the nanocrystal, an amine functionality.

In some embodiments, a class of water-soluble ligands includes thiols, such as glutathione, tiopronin, 2-mercaptoethanol, 1-thioglycerol, L-cysteine, L-cysteine ethyl ester, 2-mercaptoethylamine, thioglycolic acid, 2-(dimethylamino)ethanethiol, N-acetyl-L-cysteine, dithiothreitol, and/or derivatives thereof. In some cases, these and other ligands may form tightly-packed structures (e.g., SAMs) on the surface of the nanocrystal.

In some particular embodiments, biocompatible water-soluble ligands are particularly suitable for coating nanocrystals that are used for interaction with cells (e.g., mammalian or bacterial cells) and/or biological material including nucleic acids, polypeptides, etc. For instance, glutathione-coated ternary or higher alloyed nanocrystals may be more biocompatible and less cytotoxic than other water-soluble nanocrystals. In some cases, water-soluble ligands that can be incorporated into an aqueous synthesis of nanocrystals can produce water-soluble nanocrystals that are more biocompatible and/or less cytotoxic than nanocrystals prepared through organic or organometallic synthesis routes.

The ligand may interact with the nanocrystal to form a bond with the nanocrystal, such as a covalent bond, an ionic bond, a hydrogen bond, a dative bond, or the like. The interaction may also comprise Van der Waals interactions. Sometimes, the ligand interacts with the nanocrystal by chemical or physical adsorption.

In some embodiments, the coating may be appropriately functionalized to impart desired characteristics (e.g., surface properties) to the nanocrystal. For example, the coating may be functionalized or derivatized to include compounds, functional groups, atoms, or materials that can alter or improve properties of the nanocrystal. In some embodiments, the coating may comprise functional groups which can specifically interact with an analyte to form a covalent bond. In some embodiments, the coating may include compounds, atoms, or materials that can alter or improve properties such as compatibility with a suspension medium (e.g., water solubility, water stability, i.e., at certain pH ranges), photo-stability, and biocompatibility. In some cases, the coating may comprise functional groups selected to possess an affinity for the surface of the nanocrystal.

In certain embodiments of the invention, a thin coating of a ligand (e.g., a water-soluble ligand) on a ternary or higher alloyed nanocrystal can be prepared. For instance, the coating may have a thickness of less than or equal to 10 nm, less than or equal to 5 nm, less than or equal to 3 nm, less than or equal to 2 nm, less than or equal to 1 nm, less than or equal to 0.5 mm, or less than or equal to 0.3 nm. Thin coatings are particularly suitable for applications that require very small nanocrystal structures (e.g., less than 6 nm), such as applications involving fluorescence resonance energy transfer (FRET). In such cases, nanocrystals having water-soluble coatings can be used in FRET applications to study, i.e., protein-protein interactions, protein-DNA interactions, and protein conformational changes.

In some embodiments, the coating may interact with an analyte to form a bond with the analyte, such as a covalent bond (e.g., carbon-carbon, carbon-oxygen, oxygen-silicon, sulfur-sulfur, phosphorus-nitrogen, carbon-nitrogen, metal-oxygen or other covalent bonds), an ionic bond, a hydrogen bond (e.g., between hydroxyl, amine, carboxyl, thiol and/or similar functional groups, for example), a dative bond (e.g., complexation or chelation between metal ions and monodentate or multidentate ligands), or the like. The interaction may also comprise Van der Waals interactions. In one embodiment, the interaction comprises forming a covalent bond with an analyte. The coating may also interact with an analyte via a binding event between pairs of biological molecules. For example, the coating may comprise an entity, such as biotin that specifically binds to a complementary entity, such as avidin or streptavidin, on a target analyte.

In some embodiments, the analyte may be a chemical or biological analyte. The term “analyte,” may refer to any chemical, biochemical, or biological entity (e.g., a molecule) to be analyzed. In some cases, nanocrystals of the present invention may have high specificity for the analyte, and may be, e.g., a chemical, biological, explosives sensor, or a small organic bioactive agent (e.g., a drug, agent of war, herbicide, pesticide, etc.). In some embodiments, the analyte comprises a functional group that is capable of interacting with at least a portion of the nanocrystal. For example, the functional group may interact with the coating of the article by forming a bond, such as a covalent bond.

The coating may also comprise a functional group that acts as a binding site for an analyte. The binding site may comprise a biological or a chemical molecule able to bind to another biological or chemical molecule in a medium, e.g., in solution. For example, the binding site may be capable of biologically binding an analyte via an interaction that occurs between pairs of biological molecules including proteins, nucleic acids, glycoproteins, carbohydrates, hormones, and the like. Specific examples include an antibody/peptide pair, an antibody/antigen pair, an antibody fragment/antigen pair, an antibody/antigen fragment pair, an antibody fragment/antigen fragment pair, an antibody/hapten pair, an enzyme/substrate pair, an enzyme/inhibitor pair, an enzyme/cofactor pair, a protein/substrate pair, a nucleic acid/nucleic acid pair, a protein/nucleic acid pair, a peptide/peptide pair, a protein/protein pair, a small molecule/protein pair, a glutathione/GST pair, an anti-GFP/GFP fusion protein pair, a Myc/Max pair, a maltose/maltose binding protein pair, a carbohydrate/protein pair, a carbohydrate derivative/protein pair, a metal binding tag/metal/chelate, a peptide tag/metal ion-metal chelate pair, a peptide/NTA pair, a lectin/carbohydrate pair, a receptor/hormone pair, a receptor/effector pair, a complementary nucleic acid/nucleic acid pair, a ligand/cell surface receptor pair, a virus/ligand pair, a Protein A/antibody pair, a Protein G/antibody pair, a Protein L/antibody pair, an Fc receptor/antibody pair, a biotin/avidin pair, a biotin/streptavidin pair, a drug/target pair, a zinc finger/nucleic acid pair, a small molecule/peptide pair, a small molecule/protein pair, a small molecule/target pair, a carbohydrate/protein pair such as maltose/MBP (maltose binding protein), a small molecule/target pair, or a metal ion/chelating agent pair. In some cases, the nanocrystals may be used in applications such as drug discovery, the isolation or purification of certain compounds, and/or implemented in assays or high-throughput screening techniques.

The following examples are intended to illustrate certain embodiments of the present invention, but are not to be construed as limiting and do not exemplify the full scope of the invention.

### Example 1

This example shows a method of synthesizing glutathione-coated ZnSe nanocrystals in aqueous solution, according to one embodiment of the invention. Chemicals of high purity were purchased from either Lancaster (L-glutathione, sodium hydroxide, zinc chloride, cadmium chloride, 2-propanol) or Sigma-Aldrich (selenium powder (200 mesh), sodium borohydride).

The synthesis of ZnSe nanocrystals was based on the reaction of zinc chloride and sodium hydroselenide. All the reactions were carried out in oxygen-free water under argon atmosphere. Sodium hydroselenide was prepared by mixing sodium borohydride and selenium powder in water. After selenium powder was completely reduced by NaBH₄, the freshly prepared NaHSe solution was added to another solution containing ZnCl₂ and glutathione (GSH) at a pH of 11.5 with vigorous stirring. The amounts of Zn, Se and GSH were 5, 2 and 6 mmol, respectively, in a total volume of 500 ml. The resulting mixture was heated to 95° C., and the growth of GSH-coated ZnSe nanocrystals took place soon after. The fluorescence emissions of the nanocrystals changed from 350 μm to 370 nm after 60 min of aging. The as-prepared nanocrystals (with 370 nm emissions) were precipitated and washed several times with 2-propanol. The pelletized nanocrystals were dried at room temperature in vacuum overnight; the final product could be re-dissolved in water in the powder form.

The fluorescence emission peak of the as-prepared ZnSe nanocrystals was shifted from 350 nm to 370 nm in 90 min, with quantum yield increasing from 2% to 7%. The absorption and fluorescence spectra of as-prepared ZnSe nanocrystals with 370-nm emission are shown in FIG. 1. The quantum yield and bandwidth of ZnSe fluorescence emissions were 7% and 19 nm, respectively, and were dominated by band-gap emission. With further heating, the emission peak continued to shift towards longer wavelength, but the quantum yield began to decrease, probably due to the geometrical mismatch between the glutathione and the larger ZnSe nanocrystals. Advantageously, the GSH-coated ZnSe nanocrystals achieved 7% quantum yield without any post-preparative treatments, which can be time-consuming, and may result in irreversible agglomeration of nanocrystals.

Absorption and fluorescence spectra of nanocrystals samples in aqueous solution were recorded at room temperature on an Agilent 8453 UV-Vis spectrometer and a Jobin Yvon Horiba Fluorolog fluorescence spectrometer, respectively. The fluorescence quantum yield of nanocrystals was determined from the integrated fluorescence intensities of the nanocrystals and the reference (fluorescein solution in basic ethanol, quantum yield=97%) under 470-nm excitation. The nanocrystals samples for spectral measurement were all diluted to yield absorption of 0.1 at 470 nm.

This example shows that ZnSe nanocrystals coated with GSH can be prepared in aqueous solution according to certain embodiments of the invention.

### Example 2

This example shows a method of synthesizing glutathione-capped ZnₓCd₁₋ₓSe alloyed nanocrystals in aqueous solution, according to another embodiment of the invention. The ZnₓCd₁₋ₓSe alloyed nanocrystals were prepared through the incorporation of cadmium ions into the ZnSe precursor nanocrystals. After 30 min of heating at 95° C., the fluorescence emission of the as-prepared ZnSe precursor nanocrystals was 360 nm. CdCl₂ (1-7 mmol) pre-mixed with an equivalent amount of GSH was added dropwise to the ZnSe nanocrystals precursor solution. The solution pH was then adjusted to 11.5 with an appropriate amount of 1 M NaOH solution. After heating at 95° C. for 4 h, the resulting ZnₓCd₁₋ₓSe alloyed nanocrystals were precipitated with a minimal amount of 2-propanol, followed by resuspension in a minimal amount of deionized water. Excess salts were removed by repeating this procedure five times, and the purified nanocrystals were vacuum-dried to a powder form.

To control the Cd mole fraction in the alloyed nanocrystals, different mole ratios of Cd precursor were introduced to the ZnSe nanocrystals at the same time point, and were heated for the same duration. The fluorescence spectra of Zn_{0.75}Cd_{0.25}Se, Zn_{0.62}Cd_{0.38}Se and Zn_{0.4}Cd_{0.6}Se nanocrystals are shown in FIGS. 1(b), 1(c), and 1(d), respectively. The fluorescent peaks of the Zn_{0.75}Cd_{0.25}Se, Zn_{0.62}Cd_{0.38}Se, and Zn_{0.4}Cd_{0.6}Se alloyed nanocrystals were located at 428, 448 and 474 nm, respectively, with vary narrow bandwidths of 28, 30 and 32 nm. The quantum yields of these nanocrystal structures were 12%, 20% and 22%, respectively, in aqueous solution (pH 9, 25° C.). In another embodiment, Zn_{0.4}Cd_{0.6}Se nanocrystals having a quantum yield of 27% were synthesized in aqueous solution. The Zn molar fraction (x) in the ZnₓCd₁₋ₓSe alloyed nanocrystals was determined by ICP-MS elemental analysis. FIG. 3 illustrates the fluorescence peak emissions and quantum yields of ZnₓCd₁₋ₓSe alloyed nanocrystals having various compositions. Advantageously, the alloyed nanocrystals were stable in aqueous solution at pH 8.5-11 for longer than 7 months, and at pH 7-8 for at least 3 days without significant changes in emission properties.

This example shows that highly stable ternary or higher alloyed nanocrystals can be synthesized in aqueous solution according to certain embodiments of the invention.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of”, when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A method of preparing a ternary or higher alloyed nanocrystal, comprising:
providing at least first and second nanocrystal precursors;
forming a nanocrystal structure comprising the at least first and second nanocrystal precursors in an aqueous or water-soluble solvent;
providing at least a third nanocrystal precursor and a water-soluble ligand; and
forming a ternary or higher alloyed nanocrystal comprising the at least first, second, and third nanocrystal precursors in an aqueous or water-soluble solvent, wherein the ligand coats at least a portion of the surface of the ternary or higher alloyed nanocrystal.

2. A method as in claim 1, wherein the ternary or higher alloyed nanocrystal is formed in an inert atmosphere.

3. A method as in claim 1, wherein the ternary or higher alloyed nanocrystal is formed in water.

4. A method as in claim 1, wherein the nanocrystal structure is formed at a temperature of less than or equal to 100° C.

5. A method as in claim 1, wherein the ternary or higher alloyed nanocrystal is formed at a temperature of less than or equal to 100° C.

6. A method as in claim 1, wherein the nanocrystal structure comprising the at least first and second nanocrystal precursors is formed in the presence of a water-soluble ligand.

7. A method as in claim 1, wherein the ternary or higher alloyed nanocrystal is formed in the presence of a water-soluble ligand.

8. A method as in claim 1, wherein the water-soluble ligand comprises an amine-terminating group.

9. A method as in claim 1, wherein the water-soluble ligand comprises glutathione or a derivative thereof.

10. A method as in claim 1, wherein the ternary or higher alloyed nanocrystal has a cubic crystal structure.

11. A method as in claim 1, wherein the ternary or higher alloyed nanocrystal has a composition of ZnₓCd₁₋ₓSe, HgₓCd₁₋ₓTe, or PbₓCd₁₋ₓTe.

12. A method as in claim 1, wherein the ternary or higher alloyed nanocrystal is substantially homogeneous.

13. A method as in claim 1, wherein the ternary or higher alloyed nanocrystal and coating of the water-soluble ligand have a cross-sectional dimension of less than 6 nanometers.

14. A method as in claim 1, wherein the coating of the water-soluble ligand on the ternary or higher alloyed nanocrystal has a thickness of less than or equal to 0.5 nm.

15. A method as in claim 1, wherein the ternary or higher alloyed nanocrystal emits electromagnetic radiation in the range between 400 and 500 nm.

16. A method as in claim 1, wherein the ternary or higher alloyed nanocrystal emits electromagnetic radiation in the range between 600 and 800 nm.

17. A method as in claim 15, wherein the emission of the ternary or higher alloyed nanocrystal has a bandwidth of less than 30 nm.

18. A method as in claim 16, wherein the emission of the ternary or higher alloyed nanocrystal has a bandwidth of less than 50 mm.

19. A method as in claim 1, wherein the ternary or higher alloyed nanocrystal has a quantum yield of greater than 25% in aqueous solution.

20. A method of preparing a ternary or higher alloyed nanocrystal, comprising:
providing an aqueous or water-soluble nanocrystal precursor solution comprising a nanocrystal structure comprising at least first and second nanocrystal precursors;
mixing the nanocrystal precursor solution and a nanocrystal precursor solution comprising at least a third nanocrystal precursor; and
forming a ternary or higher alloyed nanocrystal comprising the at least first, second, and third nanocrystal precursors.

21. A method of preparing a ternary or higher alloyed nanocrystal, comprising:
providing an aqueous or water-soluble nanocrystal precursor solution comprising at least a first nanocrystal precursor;
providing an aqueous or water-soluble nanocrystal precursor solution comprising at least a second nanocrystal precursor and a water-soluble ligand;
mixing the first and second nanocrystal precursor solutions;
forming a nanocrystal structure comprising the at least first and second nanocrystal precursors;
mixing an aqueous or water-soluble nanocrystal precursor solution comprising the nanocrystal structure and an aqueous or water-soluble nanocrystal precursor solution comprising at least a third nanocrystal precursor and the water-soluble ligand; and
forming a ternary or higher alloyed nanocrystal comprising the at least first, second, and third nanocrystal precursors, wherein the water-soluble, ligand coats at least a portion of the surface of the ternary or higher alloyed nanocrystal.

22. A method of preparing a ternary or higher alloyed nanocrystal, comprising:
providing at least first and second nanocrystal precursors;
forming a nanocrystal structure comprising the at least first and second nanocrystal precursors at a temperature of less than or equal to 100 degrees Celsius;
providing at least a third nanocrystal precursor; and
forming a ternary or higher alloyed nanocrystal comprising the at least first, second, and third nanocrystal precursors at a temperature of less than or equal to 100 degrees Celsius, wherein the quantum yield of the ternary or higher alloyed nanocrystal is greater than or equal to 10% in aqueous solution.

23. A method of preparing a nanocrystal, comprising:
providing at least first and second nanocrystal precursors;
forming a nanocrystal comprising the at least first and second nanocrystal precursors in an aqueous or water-soluble solvent, wherein the nanocrystal emits electromagnetic radiation in the range between 400 and 500 nanometers, and wherein the nanocrystal has a quantum yield of at least 10% in aqueous solution.

24. A ternary or higher alloyed nanocrystal structure, comprising:
a ternary or higher alloyed nanocrystal comprising at least first, second, and third nanocrystal precursors; and
a coating of a water-soluble ligand on at least a portion of the ternary or higher alloyed nanocrystal surface, wherein the nanocrystal and coating form a ternary or higher alloyed nanocrystal structure having at least one cross-sectional dimension of less than 6 nanometers, and wherein the ternary or higher alloyed nanocrystal structure emits electromagnetic radiation in the range between 400 and 500 nanometers and has a quantum yield of at least 10% in aqueous solution.

25. A ternary or higher alloyed nanocrystal structure, comprising:
a ternary or higher alloyed nanocrystal comprising the reaction product of at least first, second, and third nanocrystal precursors; and
a coating of less than or equal to 0.5 nm thickness of an amine-terminating, water-soluble ligand on at least a portion of the ternary or higher alloyed nanocrystal surface, wherein the nanocrystal and coating form a ternary or higher alloyed nanocrystal structure that emits electromagnetic radiation in the range between 400 and 500 nanometers and has a quantum yield of at least 10% in aqueous solution.

26. A ternary or higher alloyed nanocrystal structure, comprising:
a ternary or higher alloyed nanocrystal comprising at least first, second, and third nanocrystal precursors; and
a coating comprising glutathione on at least a portion of the ternary or higher alloyed nanocrystal surface.
